(19) United States
(12) Patent Application Publication
(10) Pub. No.: US 2008/0026523 A1
(43) Pub. Date: Jan. 31, 2008

(54) Structure and method to implement dual stressor layers with improved silicide control

(75) Inventors: Yong Meng Lee, Singapore (SG); Haining S. Yang, Wappingers Falls, NY (US); Victor Chan, Newburgh, NY (US); Eng Hua Lim, Singapore (SG)

Correspondence Address: HORIZON IP PTE LTD, 8 KALLANG SECTOR, EAST WING, 7TH FLOOR, SINGAPORE 349282, 349282, omitted

(73) Assignee: CHARTERED SEMICONDUCTOR MANUFACTURING, LTD AND INTERNATIONAL BUSINESS MACHINES CORPORATION (IBM)

(21) Appl. No.: 11/495,508

(22) Filed: Jul. 28, 2006

(51) Int. Cl. H01L 21/8238

(52) U.S. Cl. 438/231

(57) ABSTRACT

An example embodiment for a method of fabrication of a semiconductor device comprises the following. We provide a substrate with a first device region and a second device region. We provide a first type FET transistor in the first device region and provide a second type FET transistor in the second device region. We form an etch stop layer over the first and second device regions and forming a first stressor layer over the first device region. The first stressor layer puts a first type stress on the substrate in the first device region. We form a second stressor layer over the second device region. The second stressor layer puts a second type stress on the substrate in the second device region. Another example embodiment is the structure of a dual stress layer device having an etch stop layer.

### BACKGROUND OF INVENTION

1) Field of the Invention

This invention relates generally to the structure and fabrication of semiconductor devices and more particularly to the structure and fabrication of a FET semiconductor devices having stressor layers and of semiconductor devices with an etch protection layer over silicide regions

2) Description of the Prior Art

The performance of MOS and other types of transistors needs to be improved as semiconductor device switching speeds continue to increase and operating voltage levels continue to decrease. The carrier mobility in a MOS transistor has a significant impact on power consumption and switching performance, where improvement in carrier mobility allows faster switching speeds. The carrier mobility is a measure of the average speed of a carrier (e.g., holes or electrons) in a given semiconductor, given by the average drift velocity of the carrier per unit electric field. Improving carrier mobility can improve the switching speed of a MOS transistor, as well as allow operation at lower voltages.

One way of improving carrier mobility involves reducing the channel length and gate dielectric thickness in order to improve current drive and switching performance.

Other attempts at improving carrier mobility include deposition of silicon/germanium alloy layers between upper and lower silicon layers under compressive stress, which enhances hole carrier mobility in a channel region. However, such buried silicon/germanium channel layer devices have shortcomings, including increased alloy scattering in the channel region that degrades electron mobility, a lack of favorable conduction band offset which may even mitigate the enhancement of electron mobility, and the need for large germanium concentrations to produce stress and thus enhanced mobility.

The importance of overcoming the various deficiencies noted above is evidenced by the extensive technological development directed to the subject, as documented by the relevant patent and technical literature. The closest and apparently more relevant technical developments in the patent literature can be gleaned by considering the following.

U.S. Pat. No. 6,573,172: Methods for improving carrier mobility of PMOS and NMOS devices—Fabrication of semiconductor device by forming P-channel and N-channel metal oxide semiconductor transistors in wafer, forming tensile film on P-channel transistor and forming compressive film on N-channel transistor—Inventor: En, William George; Milpitas, Calif.

U.S. Pat. No. 6,815,274: Inventor: Hsieh, Ming-Chang;—Resist protect oxide structure of sub-micron salicide process—Formation of resist protect oxide for sub-micron salicidation by creating patterned layer of oxide nitrogen oxide (ONO) on areas of substrate that must be shielded from salicidation.

U.S. Pat. No. 6,348,389: Chou, et al.—Method of forming and etching a resist protect oxide layer including end-point etch.—Formation and etching of resist protect oxide layer, involves forming shallow trench isolation on semiconductor substrate, and depositing and etching the resist protect oxide layer using endpoint etch mode.

U.S. Pat. No. 6,528,422: Huang et al.—Method to modify 0.25 μm 1T-RAM by extra resist protect oxide (RPO) blocking—Fabrication of one-transistor RAM device involves creating extra resist protect oxide block to prevent salicide formations at selected locations.

U.S. Pat. No. 6,686,276: Edrei, Semiconductor chip having both polycide and salicide gates and methods for making same—: Integrated semiconductor circuit fabrication involves depositing titanium silicide and refractory metal on polysilicon substrate for forming polycide and salicide transistor gates.

U.S. Pat. No. 6,468,904: Chen et al.—RPO process for selective CoSix formation—Integrated circuit device production involves dry etching top portion of composite resist protective oxide layer overlying device area to be silicided, with remaining portion being wet etched.

U.S. Pat. No. 5,252,848—Adler—Low on resistance field effect transistor.

### SUMMARY OF THE INVENTION

Some of the example embodiments of the present invention provide a structure and a method of manufacturing CMOS transistors with dual stressor layers which is characterized as follows.

An example embodiment for a method of fabrication of a semiconductor device comprises the steps of:
providing a substrate with a first device region and a second device region; providing a first type FET transistor in the first device region and providing a second type FET transistor in the second device region;
forming an etch stop layer over the first and second device regions and forming a first stressor layer over the first device region; the first stressor layer puts a first type stress on the substrate in the first device region;
forming a second stressor layer over the second device region;
the second stressor layer puts a second type stress on the substrate in the second device region.

Another example embodiment for a method of fabrication of a semiconductor device comprises the steps of:
providing a substrate with a PFET region and a NFET region;
providing a PFET transistor in the PFET region and a NFET transistor in the NFET region; the PFET transistor has PFET suicide regions; the NFET transistor has NFET silicide regions;
forming an etch stop layer over the PFET region and the NFET region;
forming a first stressor layer over the NFET region; the first stressor layer puts a tensile stress on the substrate in the NFET region;
forming a second stressor layer over the etch stop layer in the PFET region; the second stressor layer puts a compressive stress on the substrate.

An aspect of this example embodiment is the PFET transistor comprised of a PFET gate dielectric layer; a PFET gate electrode; a PFET cap layer over the PFET gate electrode; a PFET spacer, PFET source and drain regions adjacent to the gate electrode; PFET silicide regions on the PFET source and drain regions; and the NFET transistor comprised of a NFET gate dielectric layer; a NFET gate electrode; a NFET cap layer over the NFET gate electrode; a NFET spacer, NFET source and drain regions adjacent to the NFET gate electrode; NFET silicide regions on the NFET source and drain regions.

An aspect of this example embodiment is wherein the step of—forming a first stressor layer over the NFET region;—comprises

forming the first stressor layer over the substrate surface;
forming a PFET masking layer over the PFET region;
etching and removing the first stressor layer in the PFET region using the etch stop layer as an etch stop whereby the etch stop layer protects PFET suicide regions in the PFET region;
removing the PFET masking layer.

An example embodiment of a semiconductor device comprises:
a substrate with a first device region and a second device region; a first type FET transistor in the first device region and a second type FET transistor in the second device region;
an etch stop layer over the first and second device regions and a first stressor layer over the first device region; the first stressor layer puts a first type stress on the substrate in the first device region;
a second stressor layer over the second device region;
the second stressor layer puts a second type stress on the substrate in the second device region.

An aspect the example embodiment is wherein:

the first type device region is a NFET device region,

the first type FET transistor is a NFET transistor,

the second type device region is a PFET device region,

the second type FET transistor is a PFET transistor,

the first type stress is tensile stress;

the second type stress is compressive stress.

Another aspect the example embodiment is wherein:

the first type device region is a PFET device region,

the first type FET transistor is a PFET transistor,

the second type device region is a NFET device region,

the second type FET transistor is a NFET transistor,

the first type stress is compressive stress;

the second type stress is tensile stress.

An aspect the example embodiment is wherein:

the first and second type FET transistors are further comprised of silicide regions.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1 through 6 are cross sectional views for illustrating an method for manufacturing a semiconductor device according to a first example embodiment of the present invention.

FIG. 7 is a cross sectional view for manufacturing a semiconductor device according to a second example embodiment of the present invention.

### DETAILED DESCRIPTION OF THE EXAMPLE EMBODIMENTS

### I. First Example Embodiment

A. Overview

A first example embodiment shows a structure and a method of fabrication of a semiconductor device having an etch stop layer (e.g., bottom oxide layer) over a first device region of the substrate that protects underlying transistors and suicide regions from a subsequent etch of a second stressor layer. This can improve the suicide sheet resistance.

Another feature is that two different type stress layers (e.g., one compressive and one tensile) are formed on two regions of a substrate. The stress layer can increase the device performance in the two regions, especially where the two region have different device types (e.g., PFET or NFET). In a preferred embodiment, a compressive layer (e.g., 66) is formed over a NFET device region (e.g., 12) and a tensile stress layer 70 is formed over a PFET device region (e.g., 14).

B. Example Method Embodiment—Dual Stressor Layers with Etch Stop Layer to Protect Transistors

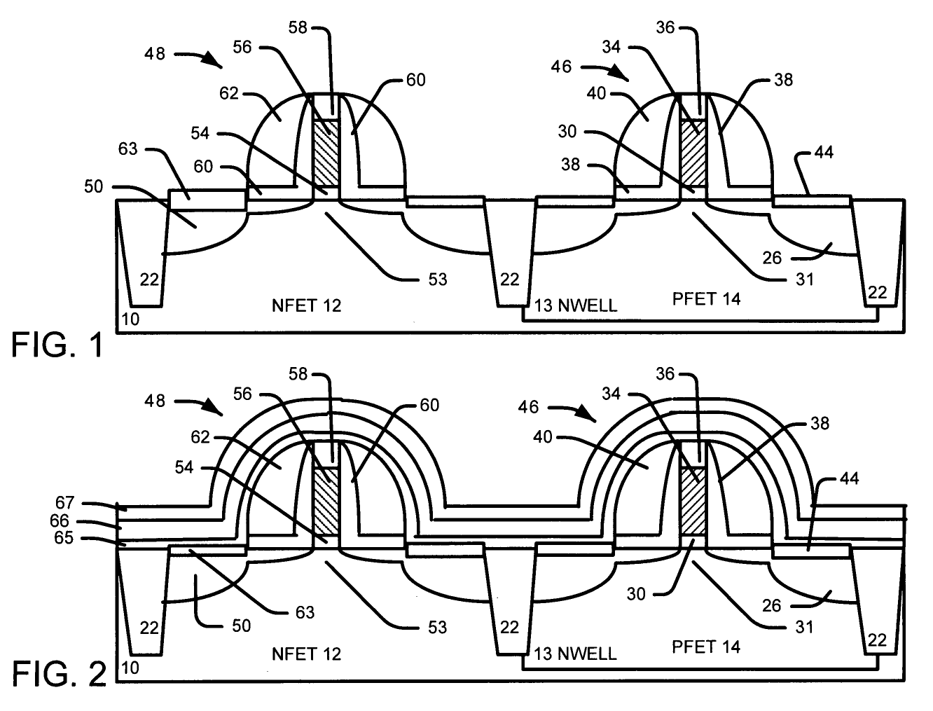

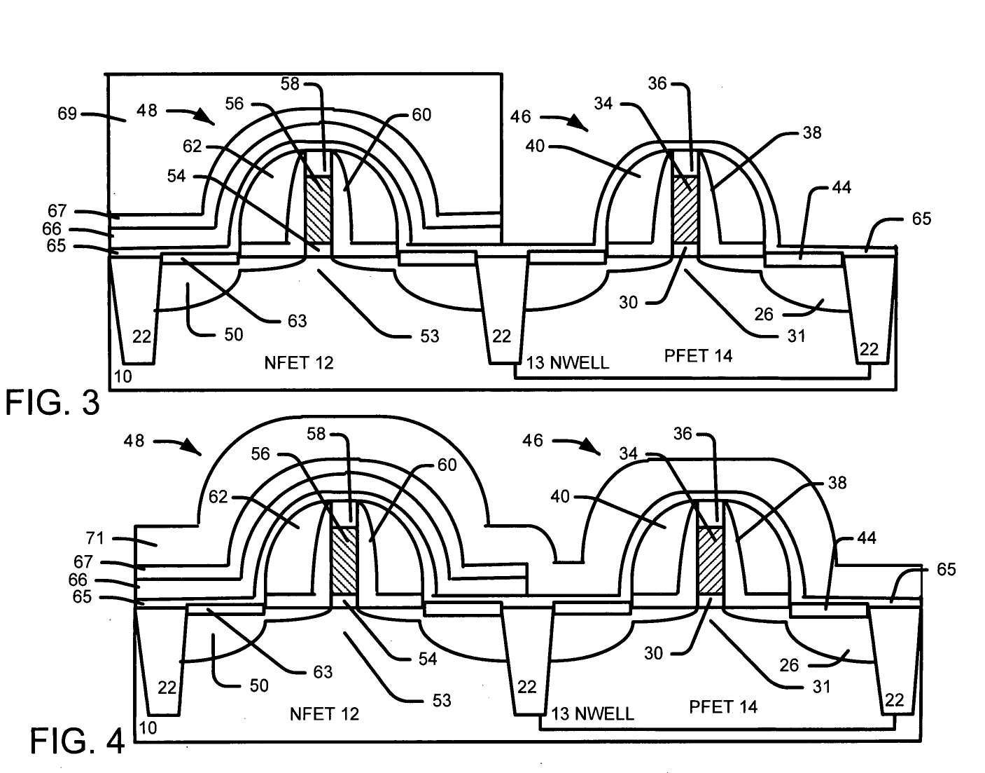

In the non-limiting example shown in FIGS. 1 thru 6, and more particularly to FIG. 2, we form a bottom oxide layer (65) over a first region (e.g., NFET region 12) of the substrate. As shown in FIG. 3, bottom oxide layer (65) protects the underlying silicide regions (44) from an etch (see FIG. 3) of a second stressor layer (e.g., middle nitride layer 66). This improves the silicide 44 sheet resistance in the first region (e.g. 14).

Also referring to FIG. 6, we form a tensile stress layer 66 over the NFET device region 12 and a compressive stress layer 70 over PFET device region 14.

The tensile stressor layer 66 induces a tensile stress on the channel of the NFET device thereby increasing the NFET carrier mobility. The compressive stressor layer 71 induces a compressive stress on the PFET channel thereby increasing the PFET carrier mobility. The stresses on the substrate regions increase the PFET and NFET device performance.

C. First Example Embodiment

The first example embodiment is shown in FIGS. 1 thru 6. Referring to FIG. 1, we provide a substrate 10 with a first region (e.g., NFET region 12) and a second region (e.g., PFET region 14).

This example description will refer to the first region as the NFET region 12 and the second region as the PFET region 14, but the regions obviously can be interchanged and this description is not limiting.

The substrate can be any semiconductor substrate and is preferably a p-doped Silicon wafer. The substrate can include doped wells such as p and n-wells. For example, FIG. 1 shows n-well 13 in the PFET region 14. Other wells can be included such as a P-well in the NFET region (not shown).

We provide a PFET transistor 46 in the PFET region 14 and a NFET transistor 48 in the NFET region 12. The PFET transistor 46 has PFET silicide regions 44. The NFET transistor 48 has NFET silicide region 63.

The PFET transistor 46 can be comprised of a PFET gate dielectric layer 30; a PFET gate electrode 34; a PFET gate silicide layer (or cap layer) 35 over the PFET gate electrode 34; a PFET spacer(s) 38 40, PFET source and drain regions 26 adjacent to the gate electrode 34; and PFET silicide regions 44 on the PFET source and drain regions 26 and PFET channel 53.

The NFET transistor 48 can be comprised of a NFET gate dielectric layer 54; a NFET gate electrode 56; a NFET gate silicide layer (or cap layer) 58 over the NFET gate electrode 56; a NFET spacer 60 62, NFET source and drain regions 50 adjacent to the NFET gate electrode 56; and NFET silicide regions 63 on the NFET source and drain regions 44 and NFET channel 31.

D. From a Dielectric Stressor Film Comprised of Two or More Dielectric Layers in the in the NFET Region 12 and a First Dielectric Layer in the PFET Region 14

Next we form an etch stop layer and first stressor layer over the substrate surface. The stressor layer can be a dielectric film is comprised of two or more dielectric layers including a first dielectric layer and a stressor layer.

In this example, referring to FIGS. 2 & 3, we form a etch stop layer 65 and first stressor layer 66 (e.g., ONO layer 65 66 67) over the substrate 10 in the NFET region 12 and we form the etch stop (e.g., bottom dielectric) layer 65 over the substrate in the PFET region 14.

This can be formed by first depositing the ONO layer 65 66 67 over the entire substrate and then patterning the NO layers 66 67 to remove the NO layers 66 67 from the PFET region 14.

For example, referring to FIG. 2, we form an ONO layer 65 66 67 over the entire substrate 10 surface. The ONO layer 65 66 67 can be comprised of a bottom oxide layer 65, a middle nitride layer 66 and a top oxide layer 67.

The etch stop layer 65 can be comprised of oxide or SiON and preferably of oxide. The etch stop layer can be comprised of a material that has an etch selectivity to the first stressor layer 66 of preferably greater than 1:4 and more preferably greater than 1:10. The etch stop layer can have a thickness between 20 and 80 angstroms.

The etch stop layer (e.g., bottom oxide layer 65) preferably has an etch selectivity ratio (using a first etchant) to the first stressor layer (e.g., N layer 66) of greater than 1:4 and more preferably greater than 1:10.

The first stressor layer (e.g., middle nitride (tensile stress) layer) 66 is preferably comprised of nitride, SiON or SiC, or other low-k dielectrics (k less than or equal to 3.0). The first stressor layer can be comprised of any material that induces the proper stress on the FET channels. The first stressor layer can be comprised of one or more layers. The first stressor layer preferably has a tensile stress preferably between +0.4 GPa and +2.6 GPa, and can have a thickness between 200 and 1200 angstroms.

The top dielectric (e.g., oxide) layer 67 can have a thickness between 100 and 300 angstroms.

Referring to FIG. 3, we form a NFET ONO mask 69 on the ONO layer that has openings over the PFET region 14.

We then etch and remove the top oxide layer 67 and the middle nitride layer 66 in the PFET region 14. The etch stops on the bottom oxide layer 65. For example, we can etch the top oxide layer 67 using a etch comprised of CF4/CH2F2. We can etch the stressor layer (e.g, middle nitride) layer 66 using an etch comprised of CF4/CH3F/O2. The etch of the stressor layer 66 can have an etch selectivity to the etch stop layer 65 using the etchant of greater than 1:4 and more preferably greater than 1:10.

A non-limiting advantage of the embodiment is that the bottom oxide layer 65 in the PFET region 14 protects the PFET silicide regions 36 44 from the etch of the middle nitride layer 66. This improves silicide region 36 44 resistance control.

Then we remove the NFET mask 69.

E. Form a Second Stressor Layer

We can form a stressor layer 71 (e.g., nitride compressive layer) 71 over the bottom oxide layer 65 and the PFET transistor 46 in the PFET region 14 and not in NFET region 12.

For example, referring to FIG. 4, we form a nitride (compressive) layer 71 over the bottom oxide layer 65 and the PFET transistor 46 in the PFET region 14 and over the ONO layer 65 66 67 in the NFET region 12.

The (compressive) nitride layer 71 can have a compressive stress between −0.4 GPa and −3.6 GPa; and a thickness between 200 and 1200 angstroms. (compressive stress is in −ve Pa while tensile is +ve.)

A compressive layer 71 induces a compressive stress on the substrate in PFET region and more preferably on the channel of the PFET transistor. The stressor layer can be comprised of any suitable material that produces a suitable stress on the substrate. For example, a compressive stressor layer 71 can be formed of SiN, Silicon oxynitride, or SiC.

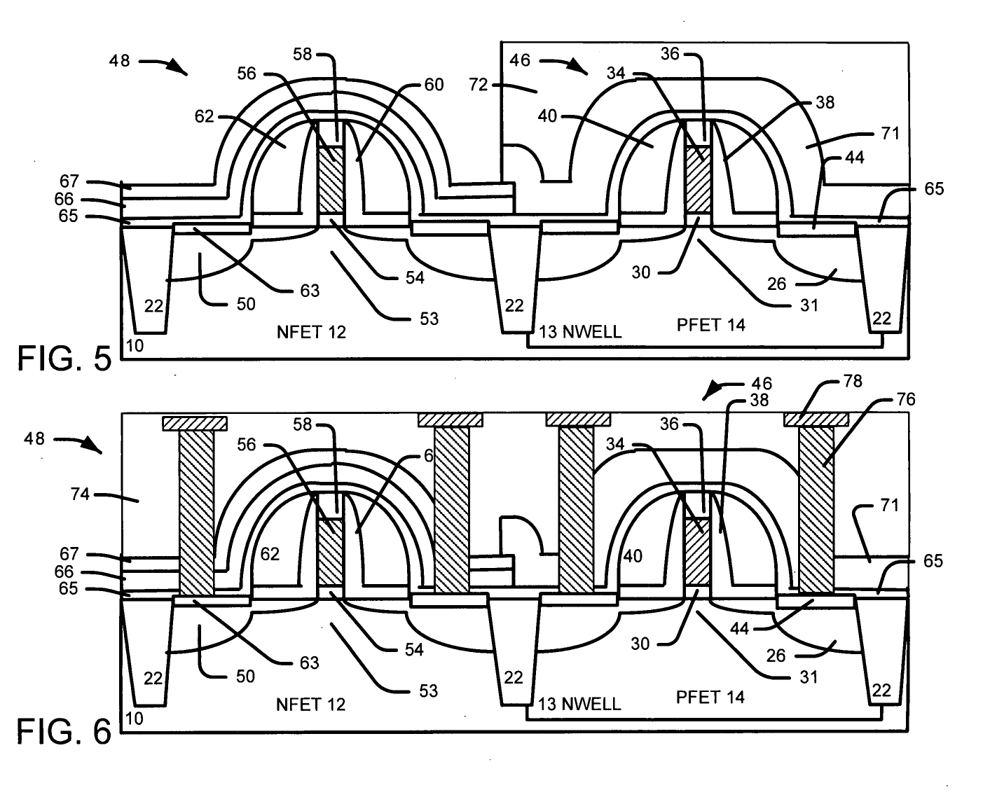

Referring to FIG. 5, we form a PFET nitride mask 72 over the nitride (compressive) layer 72 in the PFET region. The PFET nitride mask 72 has openings over the NFET regions 12.

Next, we etch and remove the nitride layer 70 in the NFET regions 12.

As shown in FIG. 6, then we remove the PFET nitride mask 72.

The bottom oxide layer 65 preferably has a thickness in the PFET region 14 equal to or less than in the NFET region 12.

F. Completing the Devices

As shown in FIG. 6, we form a dielectric layer 74 over the silicon nitride layer 70 and the NON layer 65 66 67.

Next, we form interconnects (e.g., 76 78) to contact the PFET transistor 46.

The devices are completed using additional interconnect layers and dielectric layers.

G. Second Embodiment—Change Order of Tensile and Compressive Stressor Layer Formations

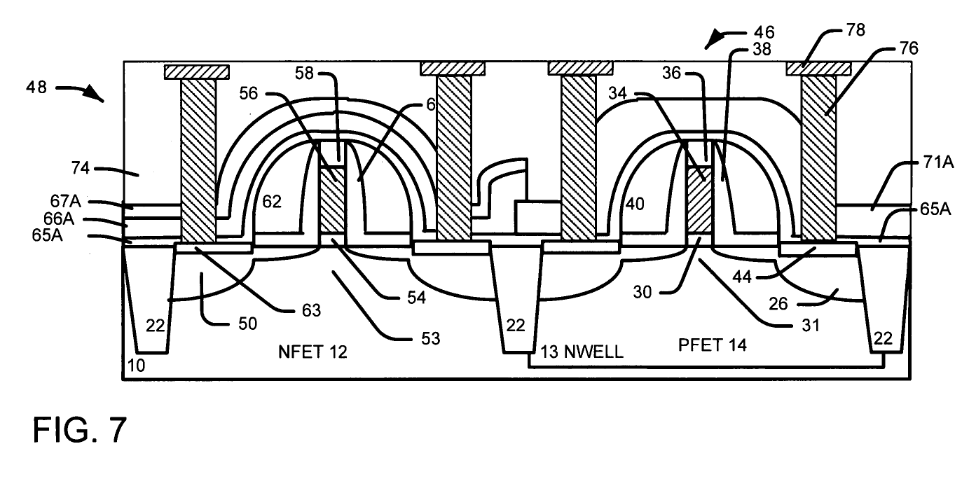

Referring to FIG. 7, in a second example embodiment, the etch stop layer 65A and the compressive stressor layer 71A can be formed before the dielectric film 66A 67A in the NFET region (e.g., NO layer 66A 67A).

Referring to FIG. 7, the bottom oxide layer 65A is formed over the entire substrate surface.

Then nitride layer 71A is formed over the entire substrate surface and then patterned to remove the layer 71A from the NFET region 12. The bottom dielectric layer (e.g., oxide layer) 65A would protect the silicide regions 63 in the NFET region 12 from the nitride etch. This would improve the silicide region 63 sheet resistance uniformity.

Then the NFET stressor layer (e.g., middle nitride layer 66A and the top oxide layer 67A) would be formed over the entire substrate surface, e.g., over the PFET stressor layer (nitride layer) 71A in the PFET region 14 and over the bottom oxide layer 65A in the NFET region 12.

The NFET stressor layer (e.g. middle nitride layer) 66A and the top oxide layer 67A are removed using a patterning process (resist mask then etch) from the PFET region 14.

Subsequent processing (e.g., contacts, interconnects and dielectric layers) can be formed as shown in FIG. 7 and as conventional in the art.

H. Non-Limiting Example Embodiments

In the above description numerous specific details are set forth such as flow rates, pressure settings, thicknesses, etc., in order to provide a more thorough understanding of the present invention. Those skilled in the art will realize that power settings, residence times, gas flow rates are equipment specific and will vary from one brand of equipment to another. It will be obvious, however, to one skilled in the art that the present invention may be practiced without these details. In other instances, well known process have not been described in detail in order to not unnecessarily obscure the present invention.

Unless explicitly stated otherwise, each numerical value and range should be interpreted as being approximate as if the word about or approximately preceded the value of the value or range.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

What is claimed is:

1. A method of fabrication of a semiconductor device comprising the steps of:
a) providing a substrate with a first device region and a second device region; providing a first type FET transistor in said first device region and providing a second type FET transistor in said second device region;
b) forming an etch stop layer over said first and second device regions and forming a first stressor layer over said first device region; said first stressor layer puts a first type stress on said substrate in said first device region;
c) forming a second stressor layer over said second device region;
d) said second stressor layer puts a second type stress on said substrate in said second device region.

2. The method of claim 1 wherein
said first type device region is a NFET device region,
said first type FET transistor is a NFET transistor,
said second type device region is a PFET device region,
said second type FET transistor is a PFET transistor,
said first type stress is tensile stress;
said second type stress is compressive stress.

3. The method of claim 1 wherein
said first type device region is a PFET device region,
said first type FET transistor is a PFET transistor,
said second type device region is a NFET device region,
said second type FET transistor is a NFET transistor,
said first type stress is compressive stress;
said second type stress is tensile stress.

4. The method of claim 1 wherein said the step of—forming the etch stop layer and the first stressor layer—further comprises:
forming said etch stop layer and the first stressor layer over said first and second device regions;
forming a first masking layer over said first device region;
etching and removing the first stressor layer in the second device region by using the etch stop layer as an etch stop whereby the etch stop layer protects the second type FET transistors from damage during the etching of the first stressor layer;
removing said first masking layer.

5. The method of claim 1 wherein the first and second type FET transistors are further comprised of silicide regions.

6. The method of claim 1 wherein said first stressor layer is comprised of a material selected from the group consisting of SiN, SiON, SiC and low-k dielectric materials with K 3.0 of less; and said etch stop layer is comprised of silicon oxide.

7. The method of claim 1 wherein the etch stop layer has an etch selectivity ratio to the first stressor layer greater than 1:10.

8. The method of claim 1 wherein the first stressor layer has a tensile stress between about +0.4 GPa and +2.6 GPa and the second stressor layer has a compressive stress between about −0.4 GPa and −3.6 GPa.

9. The method of claim 1 wherein the second stressor layer has a tensile stress between about +0.4 GPa and +2.6 GPa and the first stressor layer has a compressive stress between about −0.4 GPa and −3.6 GPa.

10. A method of fabrication of a semiconductor device comprising the steps of:
a) providing a substrate with a PFET region and a NFET region; providing a PFET transistor in said PFET region and a NFET transistor in said NFET region; said PFET transistor has PFET silicide regions; said NFET transistor has NFET silicide regions;
b) forming an etch stop layer over the PFET region and the NFET region;
c) forming a first stressor layer over the etch stop layer in the NFET region; said first stressor layer puts a tensile stress on the substrate in the NFET region;
d) forming a second stressor layer over the etch stop layer in the PFET region; said second stressor layer puts a compressive stress on the substrate.

11. The method of claim 10 which further comprises:
forming a dielectric layer over the NFET and PFET regions;
forming interconnects to contact said PFET and NFET transistors.

12. The method of claim 10 wherein
said PFET transistor comprised of a PFET gate dielectric layer; a PFET gate electrode; a PFET cap layer over said PFET gate electrode; a PFET spacer, PFET source and drain regions adjacent to said gate electrode; PFET suicide regions on said PFET source and drain regions; and
said NFET transistor comprised of a NFET gate dielectric layer; a NFET gate electrode; a NFET cap layer over said NFET gate electrode; a NFET spacer, NFET source and drain regions adjacent to said NFET gate electrode;
NFET silicide regions on said NFET source and drain regions;

13. The method of claim 10 wherein the step of—forming a first stressor layer over the NFET region;—comprises
forming the first stressor layer over the substrate surface;
forming a PFET masking layer over the PFET region;
etching and removing the first stressor layer in the PFET region using the etch stop layer as an etch stop whereby the etch stop layer protects PFET silicide regions in the PFET region;
removing the PFET masking layer.

14. The method of claim 10 wherein said etch stop layer is comprised of an oxide;
said first stressor layer is comprised of nitride;
said second stressor layer is comprised of nitride, SiON or SiC;
first stressor layer has a tensile stress between about +0.4 GPa and +2.6 GPa and the second stressor layer has a compressive stress between about −0.4 GPa and −3.6 GPa.

15. The method of claim 10 wherein a top dielectric layer is formed over the first stressor layer to form a ONO layer over the substrate.

16. A semiconductor device comprising:
a) a substrate with a first device region and a second device region; a first type FET transistor in said first device region and a second type FET transistor in said second device region;
b) an etch stop layer over said first and second device regions and a first stressor layer over said first device region; said first stressor layer puts a first type stress on said substrate in said first device region;
c) a second stressor layer over said second device region;
d) said second stressor layer puts a second type stress on said substrate in said second device region.

17. The semiconductor device of claim 16 wherein
said first type device region is a NFET device region,
said first type FET transistor is a NFET transistor,
said second type device region is a PFET device region,
said second type FET transistor is a PFET transistor,
said first type stress is tensile stress;
said second type stress is compressive stress.

18. The semiconductor device of claim 16 wherein
said first type device region is a PFET device region,
said first type FET transistor is a PFET transistor,
said second type device region is a NFET device region,
said second type FET transistor is a NFET transistor,
said first type stress is compressive stress;
said second type stress is tensile stress.

19. The semiconductor device of claim 16 wherein the first and second type FET transistors are further comprised of silicide regions.

20. The semiconductor device of claim 16 wherein said first stressor layer is comprised of a material selected from the group consisting of SiN, SiON, SiC and low-k dielectric materials with K 3.0 of less; and said etch stop layer is comprised of silicon oxide

21. The semiconductor device of claim 16 wherein the etch stop layer has an etch selectivity ratio to the first stressor layer greater than 1:10.

22. The semiconductor device of claim 16 wherein the first stressor layer has a tensile stress between about +0.4 GPa and +2.6 GPa and the second stressor layer has a compressive stress between about −0.4 GPa and −3.6 GPa.

23. The semiconductor device of claim 16 wherein the second stressor layer has a tensile stress between about +0.4 GPa and +2.6 GPa and the first stressor layer has a compressive stress between about −0.4 GPa and −3.6 GPa.
